(19) United States
(12) Patent Application Publication
(10) Pub. No.: US 2024/0096644 A1
(43) Pub. Date: Mar. 21, 2024

(54) PATTERN FORMING METHOD, MANUFACTURING METHOD OF SEMICONDUCTOR DEVICE, AND SEMICONDUCTOR DEVICE

(71) Applicant: Kioxia Corporation, Tokyo (JP)

(72) Inventors: Koki UEHA, Yokkaichi Mie (JP); Katsuyoshi KODERA, Yokohama Kanagawa (JP)

(21) Appl. No.: 18/458,056

(22) Filed: Aug. 29, 2023

(30) Foreign Application Priority Data
Sep. 20, 2022 (JP) 2022-149462

(51) Int. Cl. H01L 21/3213; G03F 7/00; H01L 21/768

(52) U.S. Cl. CPC H01L 21/32139; G03F 7/0002; H01L 21/76885; H01L 21/32135

(57) ABSTRACT

According to one embodiment, a pattern forming method uses a template having a first region with a first recessed portion and a second region adjacent to the first region. The second region has a second recessed portion therein. The recessed portions satisfy a specific relationship (D₁>2(H₁+H₂)/π), where D₁ is a shortest distance between the first and second recessed portions, H₁ is a depth of the first recessed portion, and H₂ is a depth of the second recessed portion. The pattern forming method includes placing an imprint material on an object and pressing the template against the material to mold the imprint material. The molded imprint material is then cured, and the template removed.

### CROSS-REFERENCE TO RELATED APPLICATION

This application is based upon and claims the benefit of priority from Japanese Patent Application No. 2022-149462, filed Sep. 20, 2022, the entire contents of which are incorporated herein by reference.

### FIELD

Embodiments described herein relate generally to a pattern forming method, a manufacturing method of a semiconductor device, and a semiconductor device.

### BACKGROUND

A technique of forming a fine pattern using nanoimprint lithography (NIL) is known as a manufacturing method of a semiconductor device.

### BRIEF DESCRIPTION OF THE DRAWINGS

FIG. 1 is a schematic perspective view illustrating a template.

FIG. 2 is a schematic cross-sectional of a template.

FIG. 3 is a schematic top view showing a layout example of a device pattern formed on a mesa of a template.

FIG. 4 is a schematic cross-sectional view of the layout example of the device pattern.

FIG. 5 is a schematic cross-sectional view illustrating aspects of a pattern forming method.

FIG. 6 is a schematic cross-sectional view illustrating aspects of a pattern forming method.

FIG. 7 is a schematic cross-sectional view illustrating aspects of a pattern forming method.

FIG. 8 is a schematic top view showing a layout example of a device pattern having a dummy pattern region for a first embodiment.

FIG. 9 is a schematic cross-sectional view showing the layout example of the device pattern including a dummy pattern in the first embodiment.

FIG. 10 is a schematic view illustrating aspects of an example of a deformation mechanism when the template is being separated for a device pattern that does not include a dummy pattern.

FIG. 11 is a schematic view illustrating aspects of an example of the deformation mechanism for the device pattern that does not include the dummy pattern.

FIG. 12 is a schematic view illustrating an example of a deformation mechanism when the template is separated for a device pattern including a dummy pattern.

FIG. 13 is a schematic view illustrating aspects of an example of the deformation mechanism for the device pattern including the dummy pattern.

FIG. 14 is a schematic cross-sectional view showing a certain example of shapes of recessed portions in a template.

FIG. 15 is a schematic view showing an example of a pattern of a resist layer formed using a template that satisfies Equation: D₁>2(H₁+H₂)/π.

FIG. 16 is a schematic cross-sectional view showing a first modification of a shape of each of the recessed portions.

FIG. 17 is a schematic cross-sectional view showing a second modification of a shape of each of the recessed portions.

FIG. 18 is a schematic top view showing another example of a layout of a device pattern.

FIG. 19 is a schematic top view showing another example of a layout of a device pattern.

FIG. 20 is a schematic top view showing another example of a layout of a device pattern.

FIGS. 21 to 23 are schematic cross-sectional views illustrating aspects of a manufacturing method for a semiconductor device.

### DETAILED DESCRIPTION

Embodiments describe a method of forming a desired pattern with high accuracy.

In general, according to one embodiment, a pattern forming method uses a template that has a first region with a first recessed portion and a second region adjacent to the first region. The second region has a second recessed portion therein. The recessed portions satisfy a specific relationship (D₁>2(H₁+H₂)/π), where D₁ is a shortest distance between the first and second recessed portions, H₁ is a depth of the first recessed portion, and H₂ is a depth of the second recessed portion. The pattern forming method includes placing an imprint material on an object and pressing the template against the material to mold the imprint material. The molded imprint material is then cured and the template removed.

Hereinafter, certain example embodiments will be described with reference to the drawings. The relationship between the thickness and plane dimension of each component shown in the drawings, the ratio of the thickness of each component, and the like may differ from the actual implementations of an embodiment. In the described embodiments, substantially the same components are denoted by the same reference numerals, and description thereof will be omitted as appropriate.

In a pattern forming method using NIL, a device pattern of an original plate (called a template) is pressed onto a layer of an imprint material such as an ultraviolet curable resin provided on an object (e.g., substrate, a semiconductor wafer, or the like), the layer is then irradiated with light such as ultraviolet light to cure the now-patterned layer, and the device pattern is thus transferred to the imprint material layer.

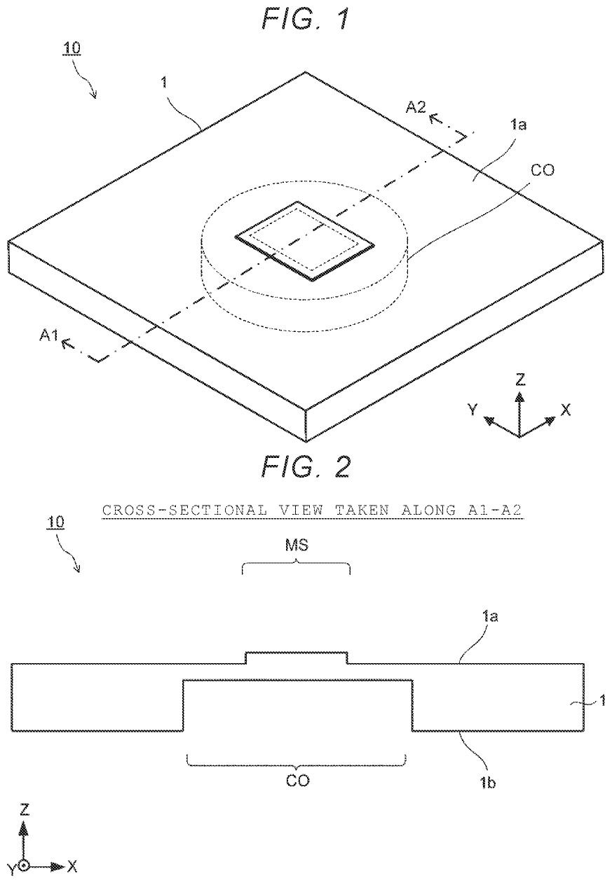

FIG. 1 is a schematic perspective view illustrating a structural example of a template. FIG. 2 is a schematic cross-sectional view illustrating the structural example of the template. FIGS. 1 and 2 each show an X-axis, a Y-axis orthogonal to the X-axis, and a Z-axis orthogonal to each of the X-axis and the Y-axis. FIG. 2 shows the cross section taken along a line segment A1-A2 shown in FIG. 1.

A template 10 includes a substrate portion 1 having a surface 1a with a mesa MS, and a surface 1b with a recessed portion CO, as shown in FIGS. 1 and 2. The mesa MS is a portion where a device pattern is formed. The planar shape of the mesa MS is not particularly limited, but is rectangular in this example. The surface 1a can be referred to as the main surface.

Examples of the substrate 1 may be quartz, for example. The substrate 1 preferably transmits the light.

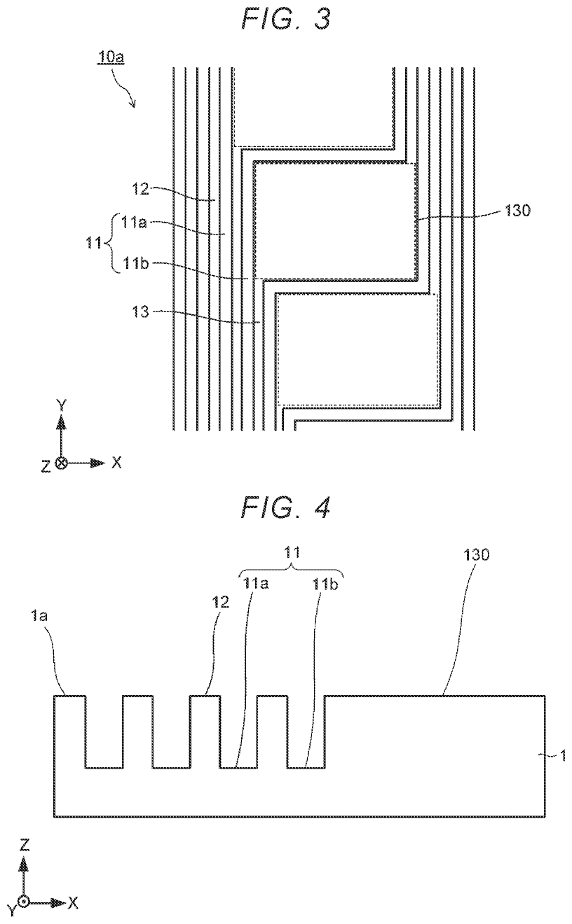

FIG. 3 is a schematic top view showing a layout example of a device pattern that can be formed on the mesa MS. FIG. 4 is a schematic cross-sectional view showing a layout example of the device pattern. FIG. 4 shows a portion of a cross section including the X-axis of the template 10 and the Z-axis of the template 10.

The device pattern 10a has recessed portions 11, protruding portions 12, and protruding portions 13. FIG. 3 shows a plurality of recessed portions 11, a plurality of protruding portions 12, and a plurality of protruding portions 13. Each of the plurality of recessed portions 11 and each of the plurality of protruding portions 12 extend, for example, along the Y-axis direction and are alternately disposed along the X-axis direction to form a line-and-space pattern.

The plurality of recessed portions 11 shown in FIG. 3 includes recessed portions 11a and recessed portions 11b. The recessed portion 11a extends along the Y-axis direction. The recessed portion 11b is the recessed portion 11 closest to the protruding portion 13. The recessed portion 11b extends between a pair of protruding portions 13, for example. In FIG. 3, the recessed portion 11b has a crank shape that bends and extends in the Y-axis direction, the X-axis direction, and the Y-axis direction again. The shape of the recessed portion 11b is not limited to the shape shown in FIG. 3. Furthermore, the recessed portion 11b may not necessarily be provided in all examples.

The protruding portion 13 is provided between recessed portions 11. The protruding portion 13 has a region 130 provided on the surface 1a adjacent to the line-and-space pattern region. The dimension of the region 130 in at least one of the X-axis direction and the Y-axis direction is greater than the width of the protruding portion 12 in the X-axis direction in FIG. 3. The dimension of the region 130 in the X-axis direction shown in FIG. 3 is greater than the width of the protruding portion 12 in the X-axis direction. The dimension of the region 130 in the Y-axis shown in FIG. 3 is also greater than the width of the protruding portion 12 in the X-axis direction.

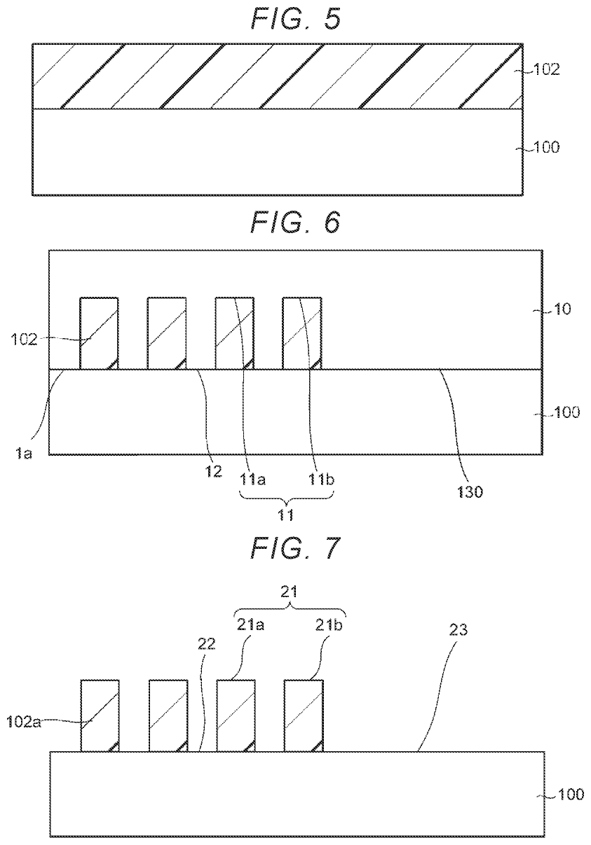

Next, a pattern forming method using the template 10 will be described. FIGS. 5, 6, and 7 are schematic cross-sectional views illustrating aspects of the pattern forming method.

In this pattern forming method, first, as shown in FIG. 5, a resist layer 102 is formed on an object 100. The object 100 is, for example, a stacked body formed by stacking at least one film on a semiconductor substrate. The configuration of the object 100 is not particularly limited. The resist layer 102 is an imprint material such as an ultraviolet curable resin, which depending on different possible embodiments may be resist material for subsequent processing of the object 100 or conductive permanent film that may remain on the object 100. The resist layer 102 can be formed by applying an imprint material to the surface of the object 100 using an inkjet method or a coating method, for example.

Next, the surface 1a of the template 10 is disposed downward above the resist layer 102, as shown in FIG. 6, the template 10 is pressed against the resist layer 102 to mold the resist layer 102, and the molded portion is cured by applying light while the template 10 is pressed against the molded resist layer 102. Although specific illustration is omitted in FIG. 6, the template 10 when pressed against the resist layer 102 leaves a residual film of the resist layer 102 between template 10 and the object 100.

After that, the template 10 is separated from the object 100, as shown in FIG. 7. Thus, the cured layer 102a of the resist layer 102 having the protruding portions 21, the recessed portions 22, and the recessed portions 23 can be formed on the object 100. FIG. 7 shows a plurality of protruding portions 21. The plurality of protruding portions 21 includes protruding portions 21a and protruding portions 21b. The protruding portion 21a is formed in a portion facing the recessed portion 11a when the template 10 is pressed. The protruding portion 21b is formed in a portion facing the recessed portion 11b when the template 10 is pressed. The recessed portion 22 is formed in a portion facing the protruding portion 12 when the template 10 is pressed. The recessed portion 23 is formed in a portion facing the region 130 of the protruding portion 13 when the template 10 is pressed.

When the pitch (width) of the protruding portions 21 is narrow and the protruding portions 21 have a high aspect ratio, the stress generated when the template 10 is separated from the object 100 may act to deform the protruding portions 21. In particular, the protruding portion 21b located at the end (edge) of the line-and-space pattern and adjacent to the recessed portion 23 is likely to be deformed by the stress. For example, if the object 100 is processed after the protruding portion 21b falls down and comes into contact with the protruding portion 21a without returning to its original state, it becomes difficult to form a desired pattern.

Accordingly, in the pattern forming method of an embodiment, a dummy pattern is formed using the template 10 having recessed portions near the ends of the line-and-space pattern.

### First Embodiment

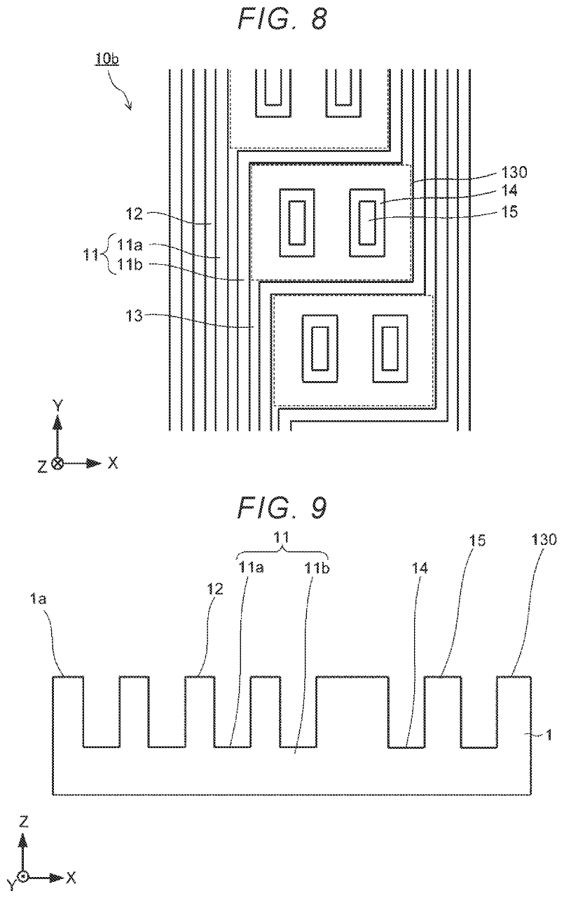

FIG. 8 is a schematic top view showing a layout example of a device pattern having a dummy pattern region in the template of a first embodiment. FIG. 9 is a schematic cross-sectional view of the device pattern including the dummy pattern in the first embodiment.

The device pattern 10b has a recessed portion 11, a protruding portion 12, a protruding portion 13, a recessed portion 14, and a protruding portion 15. The description of the device pattern 10a can be used as appropriate for the description of the recessed portions 11, the protruding portions 12, and the protruding portions 13. The recessed portion 11, the protruding portion 12, the protruding portion 13, the recessed portion 14, and the protruding portion 15 can be formed by partially processing the surface 1a of the template 10 by etching using a mask such as a metal mask.

The recessed portions 14 and the protruding portions 15 form the dummy patterns. The recessed portion 14 is provided in the region 130 of the protruding portion 13. The protruding portion 15 is surrounded by the recessed portion 14 in the region 130. FIG. 8 shows a plurality of recessed portions 14 and a plurality of protruding portions 15. The number of recessed portions 14 is not particularly limited. Although the recessed portion 14 shown in FIG. 8 is annular, the shape of the recessed portion 14 is not particularly limited. The protruding portion 15 has, for example, the same height as the protruding portion 12. It should be noted that that the protruding portion 15 need not necessarily be provided in all embodiments.

By forming a dummy pattern in the region 130, the deformation of the protruding portion 21 can be reduced. The reason for this is thought to be due to, but is not limited to, the following mechanisms.

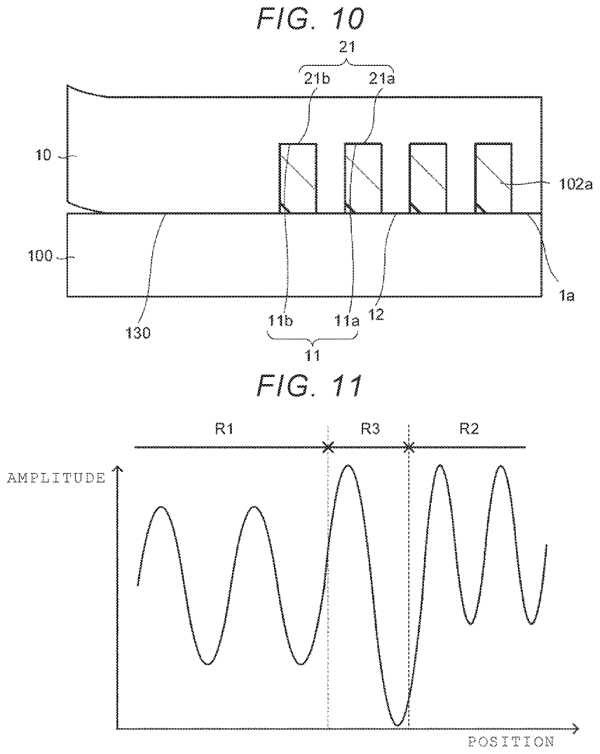

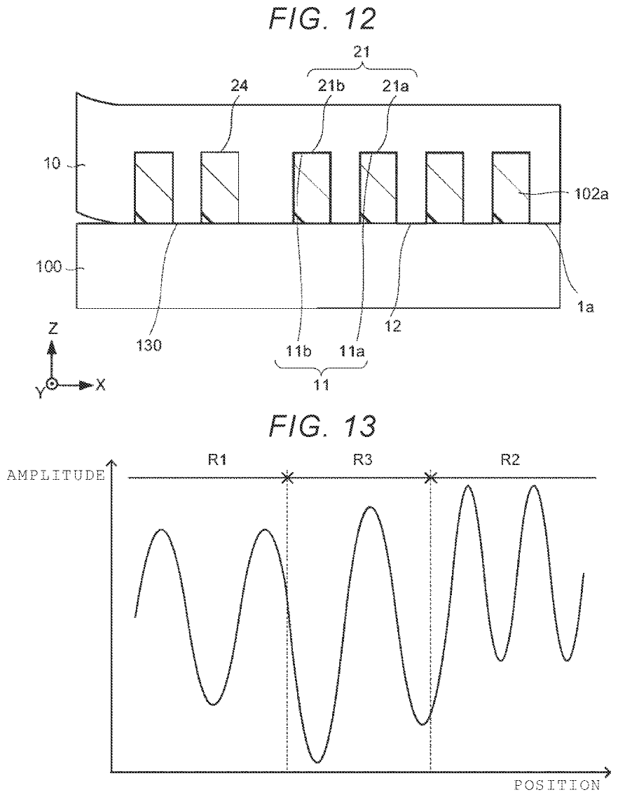

FIGS. 10 and 11 are schematic views illustrating an example of a deformation mechanism of the device pattern 10a that does not include a dummy pattern when the template 10 is separated from the resist layer 102. FIGS. 12 and 13 are schematic views illustrating an example of a deformation mechanism of the device pattern 10b including a dummy pattern when the template 10 is separated. Although FIGS. 10 and 12 show that the template 10 is bent and separated, the template 10 can, in some instances, actually be separated without being noticeably bent.

After molding the resist layer 102, as shown in FIG. 10, a “Stick-Slip” vibration occurs when the template 10 having no dummy pattern is separated from the object 100 from the region 130 side, for example. Stick-Slip vibration is a self-excited or induced vibration that occurs at the friction surface between the template 10 and the now cured resist layer 102 when the template 10 is being removed. As shown in FIG. 11, the amplitude of the Stick-Slip vibration changes greatly in a region R3 (also referred to as coverage ratio boundary) including the recessed portion 11b between a region R1 including the region 130 and a region R2 including the protruding portion 12 and the recessed portion 11a. The stress caused by this vibration causes the device pattern 10a to vibrate, and the protruding portion 21b located in the region R3 thus vibrates greatly and is likely to stick to the protruding portion 21a and/or fall down.

However, as shown in FIG. 12, when the template 10 having the dummy pattern is separated from the object 100 from the region 130 side, the stress due to Stick-Slip vibration is applied to the protruding portion 24 instead of the protruding portion 21. Thus, as shown in FIG. 13, the change in Stick-Slip vibration at the coverage ratio boundary (region R3) can be reduced as compared to the change shown in FIG. 11. Thereby, deformation of the protruding portion 21 can be reduced.

Furthermore, by adjusting the spacing between the line-and-space pattern and the dummy pattern, contact with the protruding portion 24 can be reduced even when the protruding portion 21 is deformed.

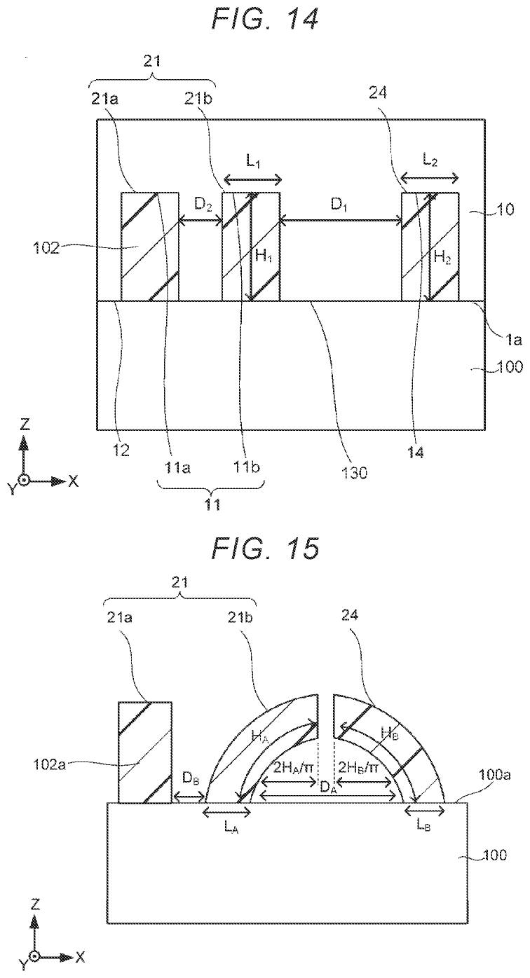

FIG. 14 is a schematic cross-sectional view showing an example of the shape of each of the recessed portions 11 and 14. For example, the template 10 preferably satisfies Equation 1 (relationship) below.

D₁>2(H₁+H₂)/π Equation 1:

Here, D₁ represents the length (shortest distance) between the recessed portion 11 (e.g., recessed portion 11b) and the recessed portion 14 that are closest to each other, H₁ represents the depth of the recessed portion 11 from the surface 1a, H₂ represents the depth of the recessed portion 14 from the surface 1a, and π represents the constant (pi). In FIG. 14, the depth H₁ and the depth H₂ have the same value. Furthermore, a length D₂ shown in FIG. 14 represents the length (shortest distance) between the recessed portions 11 that are closest to each other.

FIG. 15 is a schematic view showing an example of a pattern of a resist layer 102 formed using a template 10 that satisfies Equation 1: D₁>2(H₁+H₂)/π. FIG. 15 shows a cured layer 102a of the resist layer 102 having the protruding portion 21a, the protruding portion 21b, and the protruding portion 24. When the template 10 satisfies Equation 1: D₁>2(H₁+H₂)/π, the cured layer 102a of the resist layer 102 satisfies Equation 2 (relationship) below.

D_{A}>2(H_{A}+H_{B})/π Equation 2:

Here, D_{A} represents the length (shortest distance) between the protruding portion 21 (e.g., protruding portion 21b) and the protruding portion 24 that are closest to each other, H_{A} represents the height of the protruding portion 21b from the surface 100a of the object 100, H_{B} represents the height of the protruding portion 24 from the surface 100a, and n again represents the constant (pi). A length D_{B} shown in FIG. 15 represents the length (shortest distance) between the closest protruding portions 21.

When Equation 2: D_{A}>2(H_{A} H_{B})/π is satisfied, as shown in FIG. 15, even when the protruding portions 21b and 24 are deformed, contact between the protruding portions 21b and 24 can be prevented. Since the protruding portion 21b and protruding portion 24 that are not in contact with each other typically return to their original shapes, a desired pattern can be formed by etching using the cured layer 102a.

Preferably, the length D₁ and the length D_{A} are, for example, 5 nm or more, but no more than five times the length D₂ and the length D_{B}, respectively. When the length D₁ and the length D A exceed five times the respective lengths D₂ and D_{B}, it becomes difficult for the recessed portion 14 to reduce the change in the amplitude of the Stick-Slip vibration.

The aspect ratio (height to width) of each of the recessed portion 11, the recessed portion 14, the protruding portion 21, and the protruding portion 24 is preferably between 1.5 and 5, for example. When the aspect ratio is less than 1.5, the protruding portions 21 and 24 are less likely to fall down, so that the effect of reducing the amplitude of Stick-Slip vibration is small and perhaps of less concern. When the aspect ratio exceeds 5, the protruding portions 21 and 24 may not return to their original positions after falling down. The aspect ratio of the recessed portion 11 is defined by the depth H₁ to the width L₁ in the direction perpendicular to the length direction of the recessed portion 11 on the surface 1a. The aspect ratio of the recessed portion 14 is defined by the depth H₂ to the width L₂ in the direction perpendicular to the length direction of the recessed portion 14 on the surface 1a. The aspect ratio of the protruding portion 21 is defined by the height H_{A} to the width L_{A} in the direction perpendicular to the length direction of the protruding portion 21 on the surface 1a. The aspect ratio of the protruding portion 24 is defined by the height H_{B} to the width L_{B} in the direction perpendicular to the length direction of the protruding portion 24 on the surface 1a.

### Other Shape Examples of Recessed Portion 11 and Recessed Portion 14

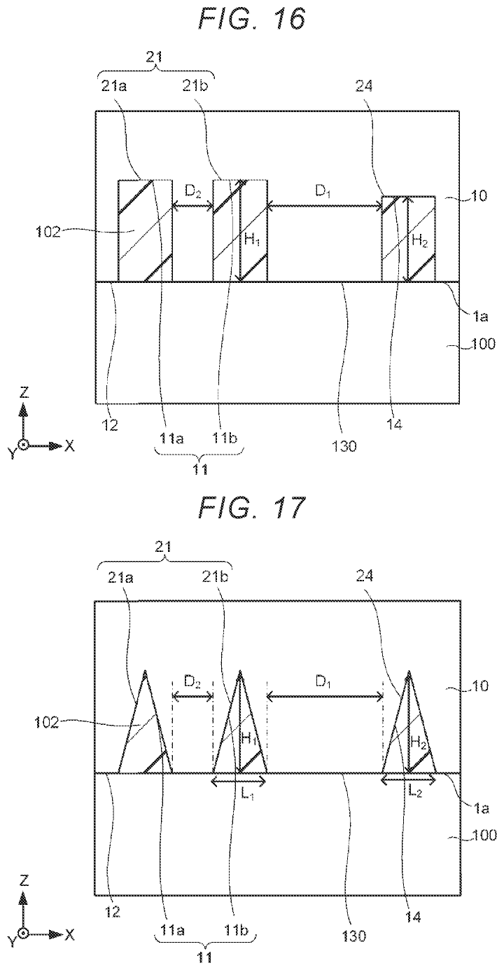

FIG. 16 is a schematic cross-sectional view showing a first modification of the shape of each of the recessed portions 11 and recessed portions 14. The recessed portions 11 and the recessed portion 14 shown in FIG. 16 differ from the recessed portions 11 and the recessed portion 14 shown in FIG. 14 in that the depth H₂ of the recessed portion 14 is less than the depth H₁ of the recessed portion 11. As described above, even when the depth H₁ and the depth H₂ are different values, if the template 10 satisfies Equation 1: D₁>2(H₁+H₂)/π, so that the resist layer 102 can satisfy Equation 2: D_{A}>2 (H_{A}+H_{B})/π, and contact between the protruding portions 21 and 24 can be prevented even if the protruding portions 21 and 24 are deformed. It should be noted that the height H₁ may be less than the height H₂. Further, the height H_{A} may be less than the height H_{B}. Further, the height H_{B} may be less than the height H_{A}.

FIG. 17 is a schematic cross-sectional view showing a second modification of the shape of each of the recessed portions 11 and 14. The recessed portions 11 and 14 shown in FIG. 17 differ from the recessed portions 11 and 14 shown in FIG. 14 in that the cross-sectional shape of the recessed portions 14 and 11 in the XZ cross section is V-shaped. The depth H₁ is defined by the depth of the deepest portion of the recessed portion 11 from the surface 1a. The depth H₂ is defined by the depth of the deepest portion of the recessed portion 14 from the surface 1a. The width L₁ is defined by the width of the widest portion of the recessed portion 11 in the direction perpendicular to the length direction. The width L₂ is defined by the width of the widest portion of the recessed portion 14 in the direction perpendicular to the length direction. The height H_{A}, the height H_{B}, the width L_{A}, and the width L_{B} are the same as the depth H₁, the depth H₂, the width L₁, and the width L₂, respectively. Even when the cross-sectional shape of the recessed portion 14 and the recessed portion 11 is a shape other than a rectangular shape, if the template 10 satisfies Equation 1: D₁>2(H₁+H₂)/π, so that the resist layer 102 and the cured layer 102a can satisfy Equation 2: D_{A}>2(H_{A}+H_{B})/π, contact between the protruding portions 21 and 24 can be prevented even when the protruding portions 21 and 24 are deformed.

### Other Layout Examples of Device Pattern

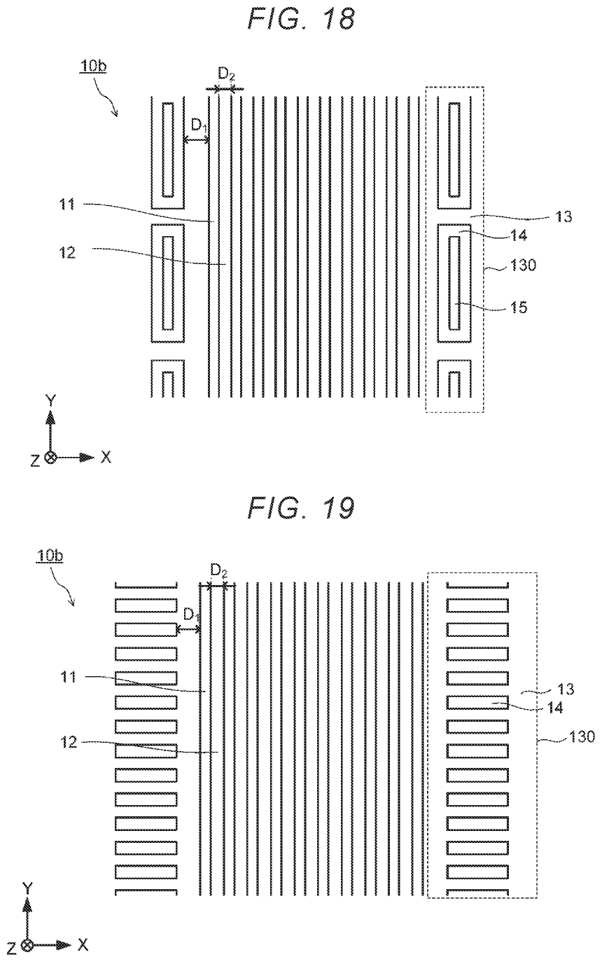

The layout of the device pattern 10b is not limited to the layout example shown in FIG. 8. FIGS. 18, 19, and 20 are schematic top views showing other examples of the layout of the device pattern 10b.

The device patterns 10b shown in FIGS. 18 to 20 have a dummy pattern including a plurality of recessed portions 14 and a plurality of protruding portions 15 in the regions 130 of the protruding portions 13 on both X-axis direction sides of a line-and-space pattern including a plurality of recessed portions 11 and a plurality of protruding portions 12.

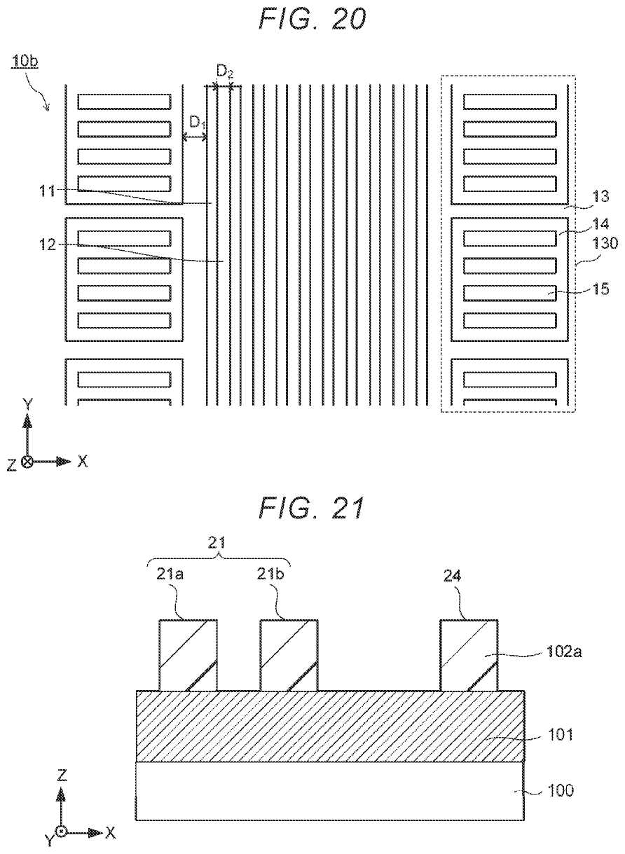

The recessed portion 14 in FIG. 18 has an annular shape surrounding the protruding portion 15. The recessed portion 14 in FIG. 19 has a strip shape extending in the X-axis direction. The recessed portion 14 in FIG. 20 has a mesh shape surrounding each of the plurality of protruding portions 15. These recessed portions 14 and the protruding portions 15, are otherwise the same as previously described.

Thus, even when the layout shapes of the device pattern 10b are different, the template 10 can satisfy Equation 1: D₁>2(H₁+H₂)/π, so that the resist layer 102 and the cured layer 102a can satisfy Equation 2: D_{A}>2(H_{A}+H_{B})/π, and contact between the protruding portions 21 and 24 can be prevented even when the protruding portions 21 and 24 are deformed when the template 10 is separated.

### Second Embodiment

FIGS. 21, 22, and 23 are schematic cross-sectional views illustrating an example of a manufacturing method of a semiconductor device. First, as shown in FIG. 21, an under layer 101 is formed on an object 100, and a cured layer 102a formed from a resist layer 102 by imprint lithography is formed on the under layer 101 using the pattern forming method of the first embodiment. The layer 101 can be an insulating layer such as a silicon oxide film. Alternatively, the under layer 101 may be a conductive layer comprising a metal material such as copper. The upper surface of the under layer 101 is partially exposed.

Next, as shown in FIG. 22, the cured layer 102a of the resist layer 102 is used to process the under layer 101 to form an under layer pattern 101a, an under layer pattern 101b, and an under layer pattern 101c. The under layer pattern 101a is formed at a position overlapping the protruding portion 21a. The under layer pattern 101b is formed at a position overlapping the protruding portion 21b. The under layer pattern 101c is formed at a position overlapping the protruding portion 24. A wiring layer or the like can be formed by selectively removing portions of a conductive under layer 101 by dry etching using the cured layer 102a of the resist layer 102 as mask or the like. The shape of the processed object 100 is determined according to the shape of the device pattern 10b. When the under layer 101 is an insulating layer, a plurality of wiring patterns can be formed by embedding a metal layer (such as copper) between the formed under layer patterns. Alternatively, after a reversal material is embedded between the under layer patterns, a metal material can be formed at the positions of the under layer patterns. When the under layer 101 is a conductive layer containing a metal material, the formed under layer pattern becomes a conductor. An example in which the under layer 101 is a conductor material will be described below. In the following description, the under layer patterns 101a, 101b and 101c are called conductors 101a, 101b and 101c, respectively.

When the resist layer 102 and the cured layer 102a satisfy Equation 2: D_{A}>2(H_{A}+H_{B})/π, the under layer 101 including the conductors 101a, 101b and 101c satisfies Equation 3 (relationship) below.

D_{X}>2(H_{X}+H_{Y})/π Equation 3:

Here, D_{X} represents the length (shortest distance) between the conductors 101b and 101c that are closest to each other, H_{X} represents the height of the conductor 101b from the surface of the object 100, H_{Y} represents the height of the conductor 101c from the surface of the object 100, π represents the constant (pi). A length D_{Y} shown in FIG. 22 represents the length (shortest distance) between the conductors 101a and 101b that are closest to each other.

The length D_{X} corresponds generally to the length D₁ and the length D_{A}. The length D_{X} is, for example, 5 nm to no more than five times the length D_{Y}. Further, the aspect ratio of each of the conductor 101a, the conductor 101b, and the conductor 101c may be, for example, 1.5 to 5. The aspect ratio of the conductors 101a and 101b is defined by the height H_{X} of the conductors 101a and 101b relative to the width L_{X} in the direction perpendicular to the length direction on the surface of the object 100. The aspect ratio of the conductor 101c is defined by the height H_{Y} of the conductor 101c to the width Ly in the direction perpendicular to the length direction.

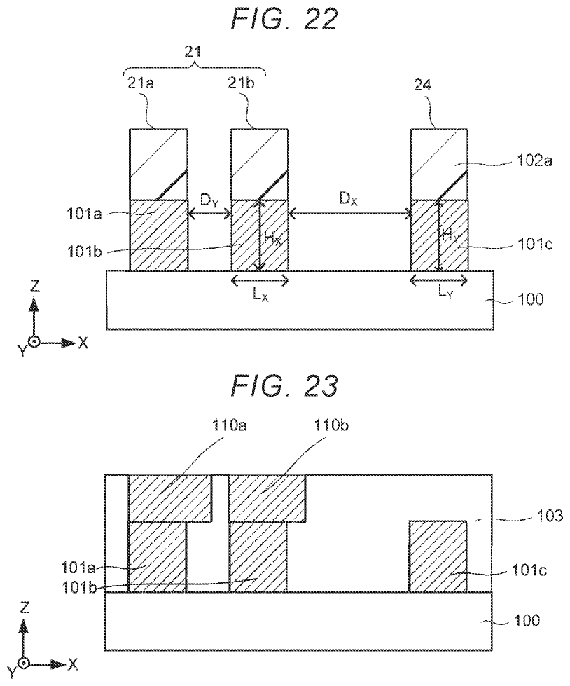

As shown in FIG. 23, an insulating layer 103 is then formed on the formed conductors 101a, 101b, and 101c, and the insulating layer 103 is processed to form openings exposing the upper surfaces of the conductors 101a and 101b, and conductors 110a and 110b are formed in these respective openings. Alternatively, the conductor 110 may be processed directly. The conductor 110a and the conductor 110b comprise a metal material such as copper. The conductors 101a and 101b and the conductors 110a and 110b are part of the device pattern and may function as embedded wiring, for example, so that the conductors 101a and 101b and the conductors 110a and 110b are not covered with the insulating layer 103. On the other hand, the conductor 101c is part of the dummy pattern and does not form a circuit, so the conductor 101c can be covered with the insulating layer 103 and is left in an electrically floating state.

As described above, in the example of the manufacturing method of a semiconductor device of the present embodiment, a semiconductor device can be manufactured by processing a conductive layer on the object 100 using the cured layer 102a of the resist layer formed by the pattern forming method of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern forming method, comprising:
placing an imprint material on an object;
pressing a first surface of a template against the imprint material on the object to mold the imprint material;
curing the molded imprint material on the object;
removing the template from cured imprint material, wherein the template has:
a first region on the first surface,
a first recessed portion in the first region,
a second region adjacent to first region on the first surface, and
a second recessed portion in the second region, and the following relationship is satisfied for the template:
D₁>2(H₁+H₂)/π
where D₁ is a shortest distance between the first recessed portion and the second recessed portion, H₁ is a depth of the first recessed portion from the first surface, and H₂ is a depth of the second recessed portion from the first surface.

2. The pattern forming method according to claim 1, wherein an aspect ratio of the second recessed portion is at least 1.5.

3. The pattern forming method according to claim 1, wherein
the first region has a plurality of first recessed portions and a plurality of first protruding portions forming a line-and-space pattern, and
the second recessed portion is a dummy pattern.

4. The pattern forming method according to claim 3, wherein the value of D₁ is less than five times the value of D₂.

5. The pattern forming method according to claim 1, wherein the value of H₂ is less than the value of H₁.

6. The pattern forming method according to claim 1, wherein the value of H₂ is the same as the value of H₁.

7. The pattern forming method according to claim 1, wherein the object is a semiconductor wafer.

8. The pattern forming method according to claim 1, further comprising:
etching the object using the cured imprint resist as a mask after removing the template.

9. The pattern forming method according to claim 1, wherein
the first recess portion extends lengthwise in a first direction along the first surface, and
the second recess portion extends lengthwise in a second direction along the first surface, the second direction intersecting the first direction.

10. The pattern forming method according to claim 1, wherein the template is quartz.

11. A manufacturing method of a semiconductor device, the method comprising:
forming a conductive layer on a semiconductor substrate;
placing an imprint material on the conductive layer;
pressing a first surface of a template against the imprint material on the conductive layer to mold the imprint material;
curing the molded imprint material on the conductive layer;
removing the template from cured imprint material, wherein the template has:
a first region on the first surface,
a first recessed portion in the first region,
a second region adjacent to first region on the first surface, and
a second recessed portion in the second region, and the following relationship is satisfied for the template:
D₁>2(H₁+H₂)/π
where D₁ is a shortest distance between the first recessed portion and the second recessed portion, H₁ is a depth of the first recessed portion from the first surface, and H₂ is a depth of the second recessed portion from the first surface.

12. The manufacturing method according to claim 11, further comprising:
etching the conductive layer using the cured imprint resist as a mask after removing the template.

13. The manufacturing method according to claim 11, wherein the second recessed portion has an aspect ratio of at least 1.5.

14. The manufacturing method according to claim 11, wherein
the first region has a plurality of first recessed portions and a plurality of first protruding portions forming a line-and-space pattern, and
the second recessed portion is a dummy pattern.

15. The manufacturing method according to claim 14, wherein the value of D₁ is less than five times the value of D₂.

16. The manufacturing method according to claim 14, wherein
the first recess portions extend lengthwise in a first direction along the first surface, and
the second recess portion extends lengthwise in a second direction along the first surface, the second direction intersecting the first direction.

17. The manufacturing method according to claim 16, wherein the value of H₂ is less than the value of H₁.

18. The manufacturing method according to claim 16, wherein the value of H₂ is the same as the value of H₁.

19. A semiconductor device, comprising:
a first layer on a semiconductor substrate;
a first pattern region of a first conductor on a surface of the first layer; and
a second pattern region of a second conductor on the surface of the first layer, the second pattern region being adjacent to the first pattern region, wherein
the second conductor is in an electrically floating state, and
the following relationship is satisfied:
D_{X}>2(H_{X}+H_{Y})/π
where D_{X} is a shortest distance between the first conductor and the second conductor, H_{X} is a height of the first conductor from the surface of the first layer, and H_{Y} is a height of the second conductor from the surface of the first layer.

20. The semiconductor device according to claim 19, wherein
the first conductor is part of a line-and-space pattern in the first pattern region, and
the second conductor is a dummy pattern.
